(19) United States
(12) Patent Application Publication
(10) Pub. No.: US 2008/0266826 A1
(43) Pub. Date: Oct. 30, 2008

(54) ASSEMBLABLE SUBSTRATE FOR IN-LINE PACKAGE AND ASSEMBLY WITH SAME

(75) Inventors: ZHEN HOU, Foshan (CN); CHING-LIANG WANG, Tu-Cheng (TW)

Correspondence Address: PCE INDUSTRY, INC.;ATT. CHENG-JU CHIANG, 458 E. LAMBERT ROAD, FULLERTON, CA, 92835, US

(73) Assignees: PREMIER IMAGE TECHNOLOGY(CHINA) LTD., Foshan City (CN); HON HAI PRECISION INDUSTRY CO., LTD., Tu-Cheng (TW)

(21) Appl. No.: 11/937,358

(22) Filed: Nov. 8, 2007

(30) Foreign Application Priority Data
Apr. 29, 2007 (CN) 200710200565.4

(51) Int. Cl. H05K 7/00; H01R 12/00

(52) U.S. Cl. 361/777; 439/55

(57) ABSTRACT

An exemplary assemblable substrate for an SIP includes a substrate and a group of welding pads. The substrate defines a receiving portion therein for receiving a line of pins of the SIP. The group of welding pads is formed on the substrate for electrically coupling the line of pins to the substrate; the group of welding pads being distributed around the receiving portion, two welding pads corresponding to two adjacent pins in the same line being distributed on opposing sides of the receiving portion.

### BACKGROUND

1. Technical Field

The invention relates to Printed Circuit Board (PCB) technology and, particularly, relates to an assemblable substrate for an in-line package and an assembly with the same.

2. Description of Related Art

FIG. 1 and FIG. 2 show two common types of in-line package: Single In-line Package (SIP) 70 and Dual In-line Package (DIP) 80. The SIP 70 includes a line of pins 71, and the DIP 80 includes two lines of pins 81.

FIG. 8 shows a typical assemblable substrate 90 for the in-line package, e.g., DIP 80. The assemblable substrate 90 can be a portion of a PCB 91 adapted to be assembled with DIP 80, and includes a substrate 92 and two lines of via holes 93 defined in an assembling surface 94 of the substrate 92. Each via hole 93 includes a drill hole 95 defined in the assemblable surface 94, and a welding pad 96 formed on the assemblable surface 94 and around the drill hole 95. The welding pads 96 have a small pitch (the distance between two adjacent welding pads 96) and bridge solder (not shown) tend to accumulate between adjacent welding pads 96 when the pins 81 of DIP 80 are soldered thereto. As such bridge solder between adjacent pads may touch each other and short circuit the pins.

Therefore, it is desirable to provide an assemblable substrate for an in-line package and an assembly with the same, which can overcome the above-mentioned problems.

### SUMMARY

In a present embodiment, an assemblable substrate for an in-line package includes a substrate and at least one group of welding pads. The substrate defines at least one receiving portion therein for respectively receiving at least one line of pins of the in-line package. The at least one group of welding pads is formed on the substrate configured for respectively electrically coupling the at least one line of pins to the substrate. Each group of welding pads is distributed around a corresponding receiving portion. Two welding pads corresponding to two adjacent pins in same line is distributed on opposing sides of the corresponding receiving portion.

### BRIEF DESCRIPTION OF THE DRAWINGS

Many aspects of the present embodiments should be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is an isometric view of an SIP;

FIG. 2 is an isometric view of a DIP;

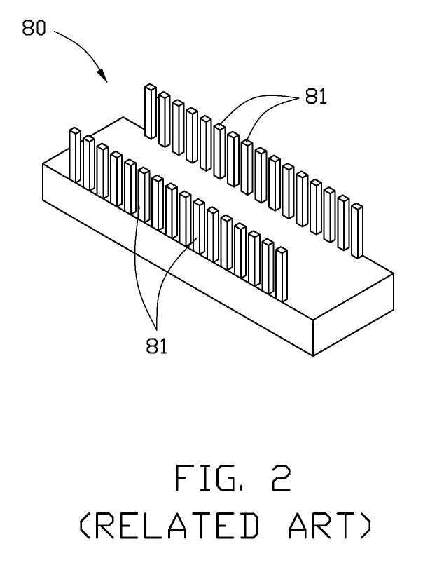

FIG. 3 is a top view of an assemblable substrate for an SIP, according to a first embodiment;

FIG. 4 is an isometric view of an assembly with the assemblable substrate, according to the first embodiment;

FIG. 5 is a top view of an assemblable substrate for an SIP, according to a second embodiment;

FIG. 6 is a top view of an assemblable substrate for a DIP, according to a third embodiment;

FIG. 7 is a top view of an assemblable substrate for a DIP, according to a fourth embodiment; and

FIG. 8 is a top view of an assemblable substrate, according to a related art.

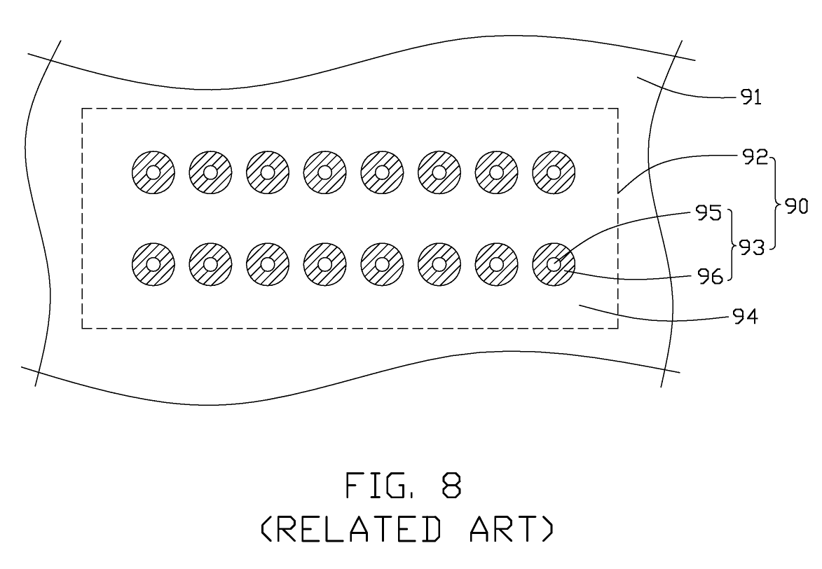

### DETAILED DESCRIPTION OF THE EMBODIMENTS

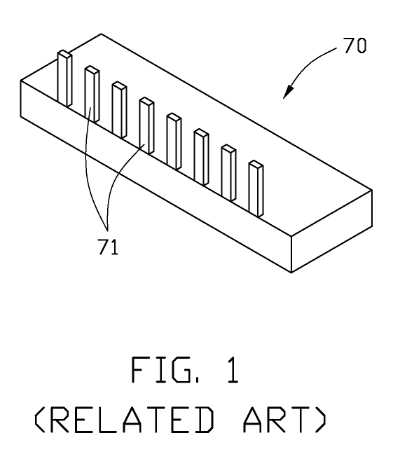

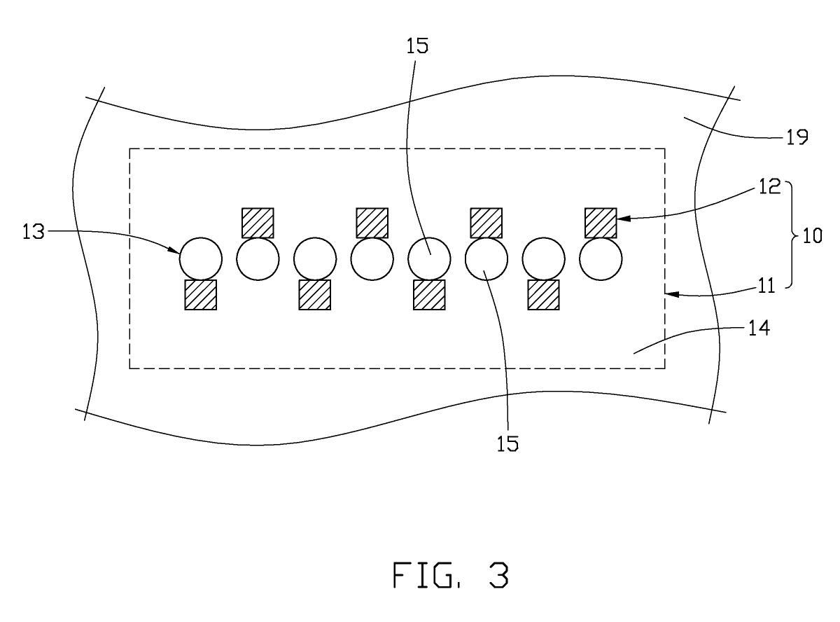

Referring FIG. 3, an assemblable substrate 10 for an SIP 70 (see FIG. 1), according to a first embodiment, includes a substrate 11 and a group of welding pads 12. The substrate 11 defines a receiving portion 13 therein for receiving a line of pins 71 of the SIP 70. The group of welding pads 12 is formed on the substrate 11 for coupling the line of pins 71 to the substrate 11. The group of welding pads 12 is distributed around the receiving portion 13. Two welding pads 12 corresponding to two adjacent pins 71 of the same line are distributed on opposing sides of the receiving portion 13.

The assemblable substrate 10 can be, typically, a portion of a PCB 19 adapted to be assembled with the SIP 70. Thus, the SIP 70 assembled to the assemblable substrate 10 will be electrically connected to other electric components (not shown) assembled to the PCB 19 to form a complete, functional circuit.

As the assemblable substrate 10 is a part of the PCB 19, the substrate 11 is, typically, a circuitized substrate including an assemblable surface 14; the receiving portion 13 is defined in the assemblable surface 14, and, accordingly, the group of welding pads 12 is formed on the assemblable surface 14 too.

The receiving portion 13 can be a line of drill holes 15 sized so as to receive the line of pins 71. Specifically, according to how many, e.g., eight, and the distribution, e.g., linear and equidistant, of the line of pins 71, the receiving portion 13 includes eight circular drill holes 15 linearly and equidistantly distributed.

Accordingly, the group of welding pads 12, in this embodiment, includes eight welding pads 12. Each welding pad 12 is placed at an edge of a corresponding drill hole 15. Thus, each welding pad 12 will contact with a corresponding pin 71 received in the corresponding drill hole 15. Two welding pads 12 corresponding to two adjacent drill holes 15 are positioned on opposing sides of the line of drill holes 15. Thus, a pitch of the welding pads 12 is enlarged.

Preferably, the welding pads 12 are essential identical in shape to get a uniform welding strength between the welding pads 12 and pins 71. The welding pads 12 on the same side of the line of drill holes 15 are linearly and equidistantly distributed. Thus, the contact surface between each welding pad 12 and the corresponding pin 71 can be larger.

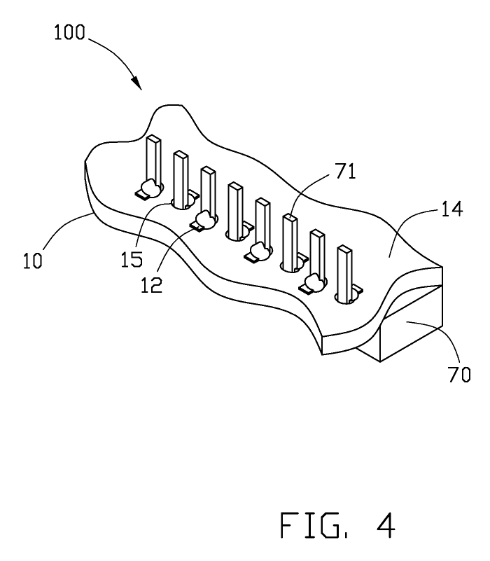

Referring to FIG. 4, an assembly 100 with the assemblable substrate 10 is shown. The line of pins 71 is inserted through the line of drill holes 15 from a surface opposing the assemblable surface 14, and is soldered with the welding pads 15 contact therewith.

The assemblable substrate 10 separates two welding pads 12 for coupling two adjacent pins 71 to the substrate 11 on opposing sides of the receiving portion 13, thus the pitch of the welding pads 12 are larger and short circuiting of adjacent pins can be avoided.

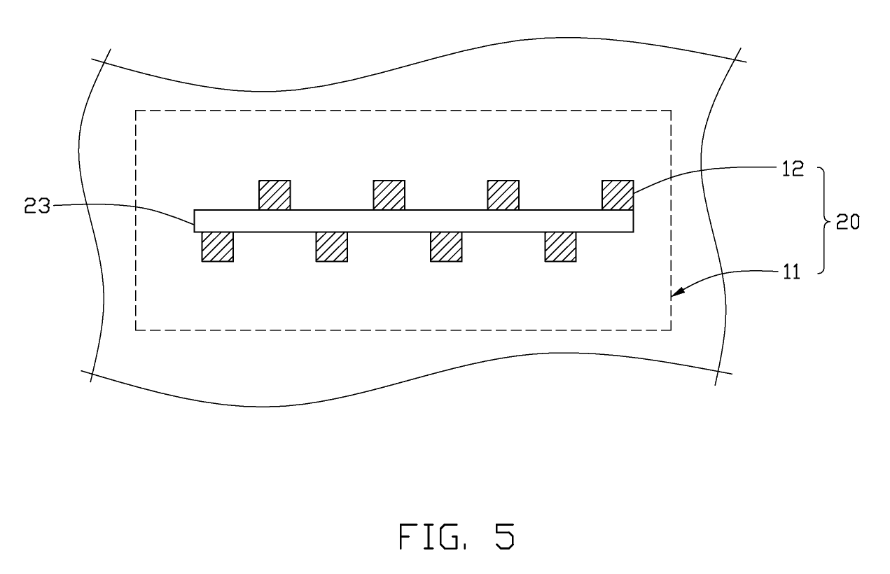

Referring to FIG. 5, another assemblable substrate 20 according to a second embodiment is shown. The assemblable substrate 20 is essentially similar to the assemblable substrate 10 except with respect to the receiving portion. In this embodiment, the receiving portion 23 is an elongate groove sized so as to receive the line of pins 71. Thus, the line of pins 71 can be more conveniently inserted through the receiving portion 23.

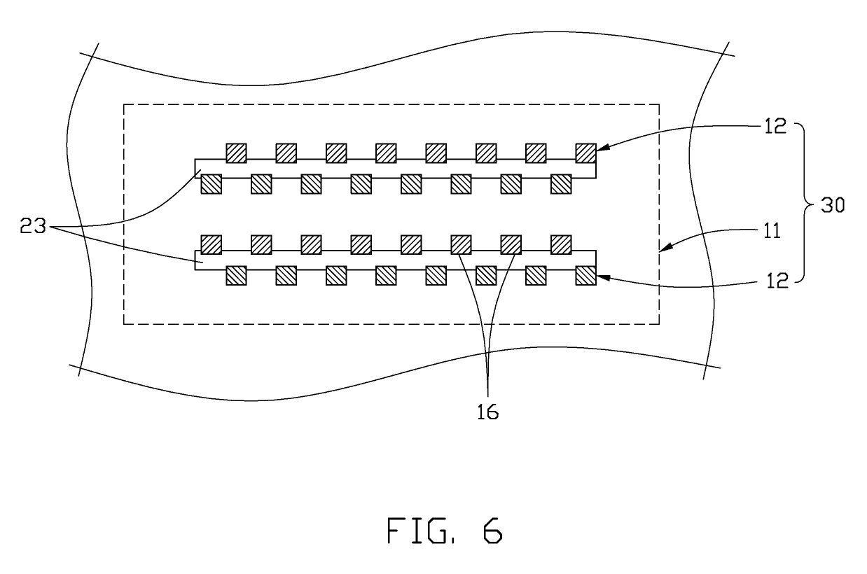

Referring to FIG. 6, another assemblable substrate 30 according a third embodiment is designed for a DIP 80. The assemblable substrate 30 is similar to the assemblable substrate 20, shown in FIG. 5, except with respect to the receiving portion 23. In this embodiment, the substrate 11 has a plurality of projections 16 in the receiving portion 23. Each projection 16 corresponds to a position of each welding pad 12. Each projection 16 projects about ¼ of the length of a side of a welding pad 12 into the receiving portion 23. Thus, each pin 81 (see FIG. 4) received in the receiving portion 23 will contact the corresponding welding pad 12 more tightly.

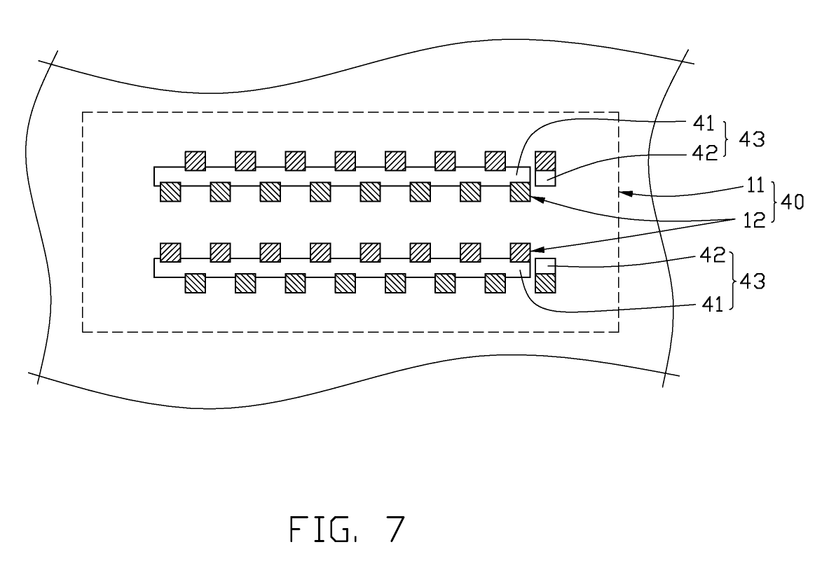

Referring to FIG. 7, another assemblable substrate 40 according to a fourth embodiment is shown. The assemblable substrate 40 is essentially similar to the assemblable substrate 30 except with respect to the receiving portion. In this embodiment, the receiving portion 43 includes a drill hole 42 and an elongated groove 41, the drill hole 42 and the elongate groove 41 are sized so as to receive a corresponding line of pins 81, each drill hole 42 is configured for receiving one pin 81 of the DIP 80. Thus, each line of pins 81 can be conveniently inserted through the corresponding elongate groove 41 and the pins is precisely aligned, with its respective welding pad 12, by the drill holes 42. Additionally, the orientation of the drill hole 42 and the elongate groove 41 will indicate the correct assembling direction of the DIP 80.

It will be understood that the above particular embodiments and methods are shown and described by way of illustration only. The principles and the features of the present invention may be employed in various and numerous embodiment thereof without departing from the scope of the invention as claimed. The above-described embodiments illustrate the scope of the invention but do not restrict the scope of the invention.

What is claimed is:

1. An assemblable substrate for an in-line package comprising:
a substrate defining at least one receiving portion therein for respectively receiving at least one line of pins of the in-line package; and
at least one group of welding pads formed on the substrate for respectively electrically coupling the at least one line of pins to the substrate, each group of welding pads being distributed around a corresponding receiving portion, two welding pads corresponding to two adjacent pins of the same line being distributed on opposing sides of the corresponding receiving portion.

2. The assemblable substrate as claimed in the claim 1, wherein the assemblable substrate is a portion of a printed circuit board.

3. The assemblable substrate as claimed in the claim 1, wherein the substrate includes an assemblable surface, the receiving portion being defined in the assemblable surface, the at least one group of welding pads being formed on the assemblable surface.

4. The assemblable substrate as claimed in the claim 1, wherein each receiving portion is a line of drill holes sized so as to receive a corresponding line of pins.

5. The assemblable substrate as claimed in the claim 1, wherein each receiving portion is an elongate groove sized so as to receive a corresponding line of pins.

6. The assemblable substrate as claimed in the claim 1, wherein each receiving portion includes at least one drill hole and at least one elongate groove, the at least one drill hole and the at least one elongate groove being sized so as to receive a corresponding line of pins, each drill hole being configured for precisely align a corresponding line of pins of the in-line package with the welding pads.

7. The assemblable substrate as claimed in the claim 5, wherein the substrate comprises a plurality of projections in each elongate groove, each projection corresponding to a position of each welding pad, each projection projecting a length less than the length of a side of the welding pad into the elongate groove.

8. The assemblable substrate as claimed in the claim 1, wherein the welding pads of the same group on the same side of the corresponding receiving portion are linearly distributed.

9. The assemblable substrate as claimed in the claim 1, wherein the welding pads of the same group and distributed on the same side of the corresponding receiving portion are equidistantly distributed.

10. The assemblable substrate as claimed in the claim 1, wherein the welding pads of the same group are essentially identical in shape.

11. An assembly comprising:
an in-line package including at least one line of pins; and
an assemlable substrate including:
a substrate defining at least one receiving portion therein, the at least one line of pins being respective received in the at least one receiving portion; and
at least one group of welding pads formed on the substrate, each group of welding pads being distributed around a corresponding receiving portion, the at least one line of pins being respectively soldered with the at least one group of welding pads, two welding pads corresponding to two adjacent pins of the same line being distributed on opposing sides of the corresponding receiving portion.

12. The assembly as claimed in the claim 11, wherein the in-line package is selected from a group of single in-line package and dual in-line package.
